(19) United States
(12) Patent Application Publication
(10) Pub. No.: US 2013/0068506 A1
(43) Pub. Date: Mar. 21, 2013

(54) PLATING SYSTEM AND METHOD OF MANUFACTURING THE SAME

(71) Applicants: Jae Il Kim, Gyunggi-do (KR); Jong Young Lee, Gyunggi-do (KR); Sang Hwa Kim, Gyunggi-do (KR)

(72) Inventors: Jae Il Kim, Gyunggi-do (KR); Jong Young Lee, Gyunggi-do (KR); Sang Hwa Kim, Gyunggi-do (KR)

(73) Assignee: SAMSUNG ELECTRO-MECHANICS CO., LTD., Gyunggi-do (KR)

(21) Appl. No.: 13/333,682

(22) Filed: Dec. 21, 2011

(30) Foreign Application Priority Data
Sep. 19, 2011 (KR) 1020110093997

(51) Int. Cl. H05K 1/00; C25D 5/02

(52) U.S. Cl. 174/250; 205/135

(57) ABSTRACT

Disclosed herein are a plating pattern and a method of manufacturing the same. The plating pattern includes: a base substrate; a conductive polymer formed on the base substrate and patterned to be selectively deactivated by having a deactivator added thereto; and a plating layer formed on portions of the conductive polymer except for the deactivated portions.

### CROSS REFERENCE TO RELATED APPLICATION

This application claims the benefit of Korean Patent Application No. 2011-0093997, filed on Sep. 19, 2011, entitled “Plating Pattern and Method of Manufacturing The Same”, which is hereby incorporated by reference in its entirety into this application.

### BACKGROUND OF THE INVENTION

1. Technical Field

The present invention relates to a plating pattern and a method of manufacturing the same.

2. Description of the Related Art

A plating pattern formed through electroplating has been variously used in a sensing electrode pattern for a touch panel, a noise shielding film, a static electricity preventing film, a circuit pattern of a printed circuit board, a transparent electrode pattern for a display, or the like.

The plating pattern according to the prior art is formed through a subtractive method. Describing a process of forming the plating pattern through the subtractive method in detail, a plating layer is first formed on a base substrate, and a photoresist is applied to the plating layer. Then, the photoresist is patterned so that an open part is formed through exposure/development processes, and the plating layer is selectively etched through the open part, thereby forming a plating pattern. However, this subtractive method has disadvantages in that a manufacturing process is complicated and a manufacturing cost is significantly high. In addition, since most of the plating layer is removed, a large amount of metal is unnecessarily consumed.

In order to solve these problems, a full additive method has been developed. In the full additive method, a photoresist is applied to a base substrate, the photoresist is patterned so that an open part is formed through exposure/development processes, and electroless plating is then performed, thereby selectively forming a plating pattern in the open part. The full additive method has solved the problem in the subtractive method that most of the plating layer is removed; however, it still has a problem such as management of an electroless plating solution, environmental pollution, or the like, such that it is difficult to be commercialized.

### SUMMARY OF THE INVENTION

The present invention has been made in an effort to provide a plating pattern capable of preventing unnecessary consumption of a metal by selectively deactivating a conductive polymer and then forming a plating layer only on portions of the conductive polymer except for the deactivated portions using the conductive polymer as a seed layer, and a method of manufacturing the same.

According to a first preferred embodiment of the present invention, there is provided a plating pattern including: a base substrate; a conductive polymer formed on the base substrate and patterned to be selectively deactivated by having a deactivator added thereto; and a plating layer formed on portions of the conductive polymer except for the deactivated portions.

The deactivator may be an oxidant.

The oxidant may be O₃, NaOCl, KMnO₄, K₂Cr₂O₇, or amine oxide.

The conductive polymer may be poly-3,4-ethylenedioxythiophene/polystyrenesulfonate (PEDOT/PSS), polyaniline, polyacetylene, or polyphenylenevinylene.

A predetermined portion of the base substrate may be depressed or protruded so that the plating layer has a three-dimensional contact surface.

According to a second preferred embodiment of the present invention, there is provided a method of manufacturing a plating pattern, the method including: (A) forming a conductive polymer on a base substrate; (B) pattering the conductive polymer so as to be selectively deactivated by adding a deactivator thereto; and (C) forming a plating layer through an electroplating process using the conductive polymer as a seed layer.

In step (B), the deactivator may be an oxidant.

In step (C), the plating layer may be formed on portions of the conductive polymer except for the deactivated portions.

The oxidant may be O₃, NaOCl, KMnO₄, K₂Cr₂O₇, or amine oxide.

The conductive polymer may be poly-3,4-ethylenedioxythiophene/polystyrenesulfonate (PEDOT/PSS), polyaniline, polyacetylene, or polyphenylenevinylene.

The method may further include, after step (B), depressing or protruding a predetermined portion of the base substrate so that the conductive polymer has a three-dimensional contact surface.

### BRIEF DESCRIPTION OF THE DRAWINGS

FIG. 1 is a cross-sectional view of a plating pattern according to a preferred embodiment of the present invention;

FIGS. 2A and 2B are perspective views showing a modified example of the plating pattern shown in FIG. 1;

FIGS. 3 to 5 are process cross-sectional views showing a method of manufacturing a plating pattern according to a preferred embodiment of the present invention in a process sequence; and

FIG. 6 is a graph showing an absorbance of ultraviolet-visible rays of poly-3,4-ethylenedioxythiophene/polystyrenesulfonate (PEDOT/PSS) on which treatment is not performed and PEDOT/PSS to which NaOCl is added, measured according to wavelengths.

### DESCRIPTION OF THE PREFERRED EMBODIMENTS

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, in describing the present invention, a detailed description of related known functions or configurations will be omitted so as not to obscure the subject of the present invention.

Hereinafter, preferred embodiments of the present invention will be described in detail with reference to the accompanying drawings.

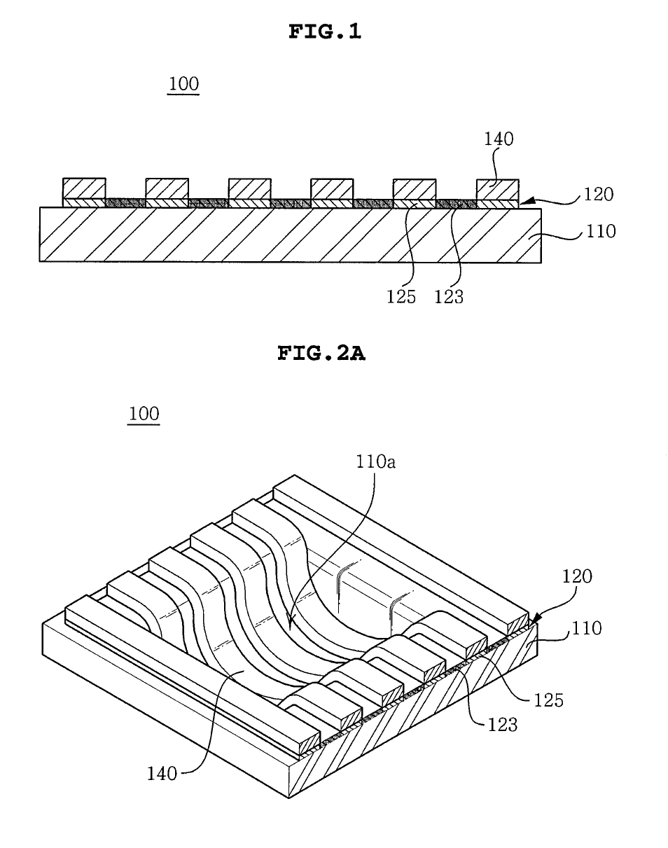

FIG. 1 is a cross-sectional view of a plating pattern according to a preferred embodiment of the present invention.

As shown in FIG. 1, the plating pattern 100 according to the present embodiment is configured to include a base substrate 110, a conductive polymer 120 formed on the base substrate 110 and patterned to be selectively deactivated by having a deactivator added thereto, and a plating layer 140 formed on portions 125 of the conductive polymer 120 except for the deactivated portions 123.

The base substrate 110 serves to provide an area at which the conductive polymer 120 and the plate layer 140 are to be formed. Here, the base substrate 110 needs to have support force capable of supporting the conductive polymer 120 and the plating layer 140 and have transparency when it is used in a touch panel, a display, or the like. In consideration of the support force and the transparency, the base substrate 110 may be made of polyethyleneterephthalate (PET), polycarbonate (PC), polymethylmethacrylate (PMMA), polyethylenenaphthalate (PEN), polyethersulfone (PES), cyclic olefin copolymer (COC), triacetylcellulose (TAC) film, polyvinyl alcohol (PVA) film, polyimide (PI) film, polystyrene (PS), biaxially oriented polystyrene (BOPS; containing K resin), glass or reinforced glass, or the like, but is not necessarily limited thereto. In addition, when the based substrate 110 is used in a printed circuit board, it may be made of a complex polymer resin that is generally used as an interlayer insulation material. The base substrate 110 may be made of, for example, a prepreg, Ajinomoto Build up Film (ABF), or an epoxy based resin such as FR-4, a Bismaleimide Triazine (BT) or the like.

The conductive polymer 120, which serves as a seed layer when the plating layer 140 is formed through electroplating, is formed on the base substrate 110. In addition, after the conductive polymer 120 is formed on the base substrate 110, the deactivator is added to the conductive polymer 120, such that the conductive polymer 12 is patterned to be selectively deactivated. More specifically, as the deactivator, an oxidant 130 (See FIG. 4) may be used. The deactivator is added only to portions 123 of the conductive polymer 120 except for portions at which the plating layer 140 is to be formed, thereby increasing sheet resistance to the infinity. A content of deactivating the conductive polymer 120 by adding the deactivator thereto will be described in detail in a method of manufacturing a plating pattern.

Meanwhile, the conductive polymer 120 includes poly-3,4-ethylenedioxythiophene/polystyrenesulfonate (PEDOT/PSS), polyaniline, polyacetylene, polyphenylenevinylene, or the like, and the oxidant 130 among the deactivator includes O₃, NaOCl, KMnO₄, K₂Cr₂O₇, amine oxide, or the like.

The plating layer 140, which is formed at portions 125 of the conductive polymer 120 except for the deactivated portions 123, is formed by an electroplating process using the conductive polymer 120 as a seed layer. More specifically, since the conductive polymer 120 has the deactivator added thereto to thereby be patterned to be selectively deactivated, only the portions 125 of the conductive polymer 120 except for the deactivated portions 123 serve as the seed layer at the time of the electroplating process. Therefore, when the electroplating process is performed, the plating layer 140 is selectively formed only on the portions 125 of the conductive polymer 120 except for the deactivated portions 123. As described above, since the plating layer 140 is selectively formed only on the portions 125 of the conductive polymer 120 except for the deactivated portions 123 after the conductive polymer 120 is selectively deactivated, a process of etching and patterning the plating layer 140 may be omitted. Therefore, it is possible to prevent a metal from being unnecessarily consumed.

Meanwhile, the plating layer 140 may be made of copper (Cu), aluminum (Al), gold (Au), silver (Ag), titanium (Ti), palladium (Pd), chromium (Cr), or a combination thereof. The plating layer 140 may be made of copper (Cu), aluminum (Al), gold (Au), or silver (Ag) having high electrical conductivity among the above-mentioned materials. However, the plating layer 140 is not limited to being made of the above-mentioned metals but may be made of any metal that has high electric conductivity and are easily processed.

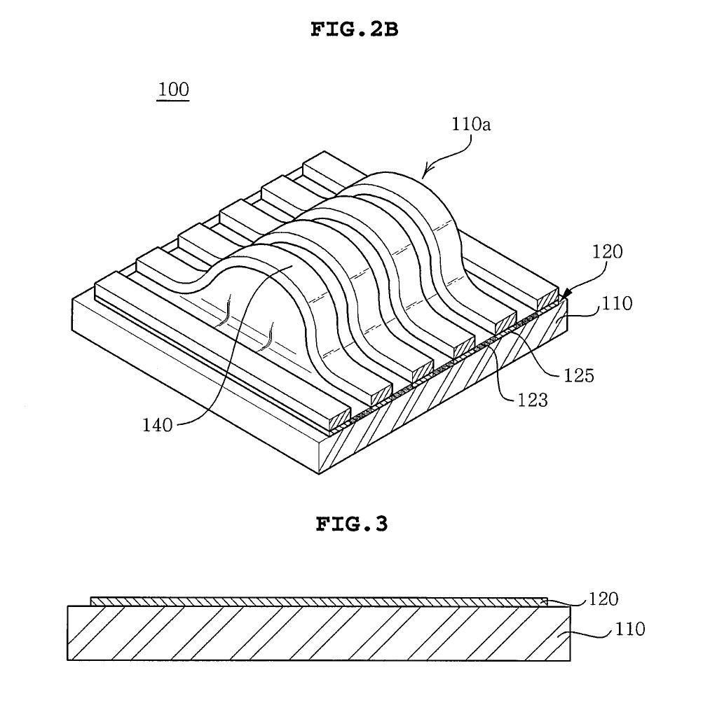

FIGS. 2A and 2B are perspective views showing a modified example of the plating pattern shown in FIG. 1.

As shown in FIGS. 2A and 2B, a plating pattern 100 according to the present embodiment may be manufactured so that a plating layer 140 has a three-dimensional contact surface by depressing or protruding a predetermined portion 110a of the base substrate 110.

More specifically, a conductive polymer 120 is formed on the base substrate 110 and is selectively deactivated, the predetermined portion 110a of the base substrate 110 is depressed (See FIG. 2A) or protruded (See FIG. 2B), and an electroplating process is then performed, thereby making it possible to form the plating layer 140 having the three-dimensional contact surface. Here, even though the predetermined portion 110a of the base substrate 110 is depressed (See FIG. 2A) or protruded (See FIG. 2B), the conductive polymer 120 has excellent flexibility, such that it is not cracked. Therefore, when the plating layer 140 is formed through the electroplating process, the conductive polymer 120 may serve as a seed layer without any problem.

The plating pattern 100 according to the preferred embodiment of the present invention may be used in a sensing electrode pattern for a touch panel, a noise shielding film, a static electricity preventing film, a circuit pattern of a printed circuit board, a transparent electrode pattern for a display, or the like. However, the plating pattern 100 according to the preferred embodiment of the present invention is not necessarily limited thereto but may be used in any field in which a plating pattern may be used.

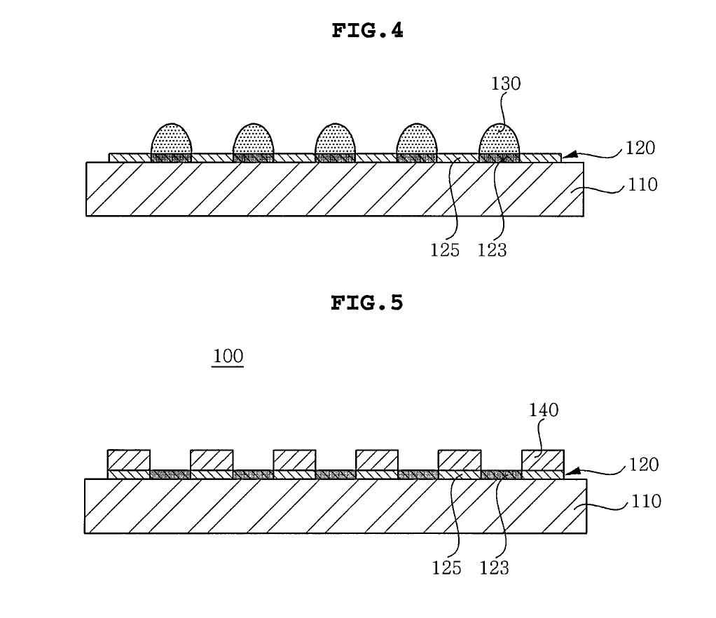

FIGS. 3 to 5 are cross-sectional views showing a method of manufacturing a plating pattern according to a preferred embodiment of the present invention in a process sequence.

As shown in FIGS. 3 to 5, the method of manufacturing a plating pattern 100 according to the present embodiment includes (A) forming a conductive polymer 120 on a base substrate 110, (B) pattering the conductive polymer 120 so as to be selectively deactivated by adding a deactivator thereto, and (C) forming a plating layer 140 through an electroplating process using the conductive polymer 120 as a seed layer.

First, as shown in FIG. 3, an operation of forming the conductive polymer 120 on the base substrate 110 is performed. Here, the conductive polymer 120 may be formed on the base substrate 110 through a dry process or a wet process. More specifically, the dry process includes a sputtering process, an evaporation process, or the like, and the wet process includes a dip coating process, a spin coating process, a roll coating process, a spray coating process, or the like. In addition, the conductive polymer 120 includes poly-3,4-ethylenedioxythiophene/polystyrenesulfonate (hereinafter, referred to as PEDOT/PSS), polyaniline, polyacetylene, polyphenylenevinylene, or the like.

Meanwhile, in order to enhance adhesion between the base substrate 110 and the conductive polymer 120, high frequency treatment or primer treatment may be performed on the base substrate 110 before the conductive polymer 120 is formed.

Then, as shown in FIG. 4, an operation of patterning the conductive polymer 120 so as to be selectively deactivated by adding a deactivator thereto is performed. Here, the deactivator may be, for example, an oxidant 130 but is not necessarily limited thereto. However, hereinafter, a case in which the oxidant 130 is used as the deactivator will be described. The oxidant 130, which is the deactivator, deactivates portions of the conductive polymer 120 at which a plating layer 140 is not to be formed to thereby increase sheet resistance to the infinity. Here, the oxidant 130, which has a paste form, may be printed on the conductive polymer 120 to thereby be added thereto, but is not necessarily limited thereto. Meanwhile, as the oxidant 130, O₃, NaOCl, KMnO₄, K₂Cr₂O₇, amine oxide, or the like, may be used. In addition, any oxidant known in the art may be used.

Meanwhile, when the oxidant 130 is NaOCl and the conductive polymer 120 is PEDOT/PSS, a specific reaction process of deactivating the conductive polymer 120 by adding the oxidant 130 thereto is represented by the following reaction formula.

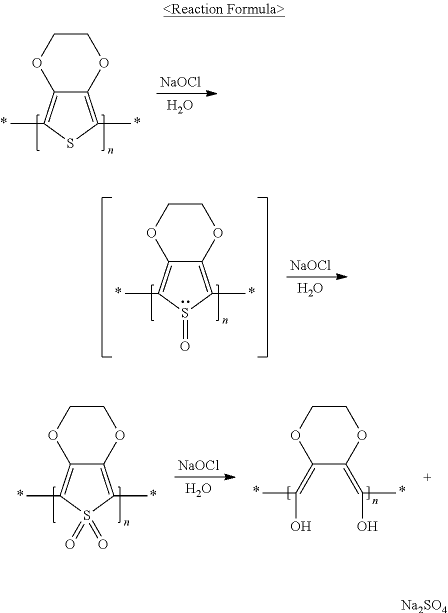

As in the above reaction formula, when NaOCl is added to PEDOT/PSS, thiophene ring in PEDOT/PSS is cleaved. As described above, when the thiophene ring is cleaved, PEDOT/PSS is deactivated while sheet resistance thereof rapidly increases.

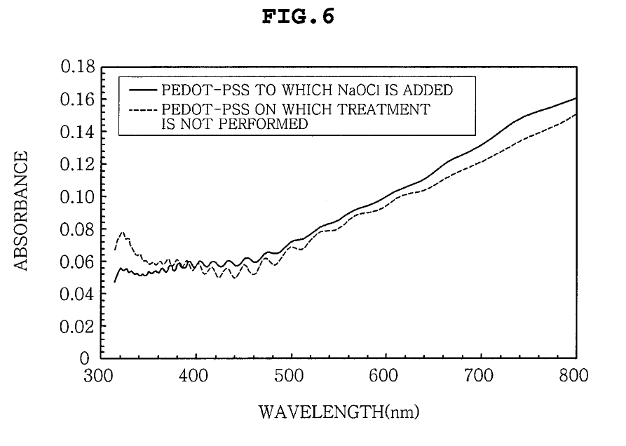

FIG. 6 is a graph showing an absorbance of ultraviolet-visible rays of PEDOT/PSS on which treatment is not performed and PEDOT/PSS to which NaOCl is added, measured according to wavelengths.

As shown in FIG. 6, there is little difference between an absorbance of PEDOT/PSS on which treatment is not performed and an absorbance of PEDOT/PSS to which NaOCl is added. As a result, since the absorbance of PEDOT/PSS according to a wavelength is hardly changed even after NaOCl is added to PEDOT/PSS, even though PEDOT/PSS is selectively deactivated by the addition of NaOCl, a user may not visually recognize the difference.

In addition, sheet resistances of PEDOT/PSS on which treatment is not performed and PEDOT/PSS to which NaOCl is added, measured based on a L*a*b* color system, which is a coloring method defined by the international commission on illumination (CIE) in 1976, are given by the following Table 1.

TABLE 1

| | Sheet Resistance | L* | a* | b* |
|---|---|---|---|---|
| PEDOT/PSS to which | 295Ω/□ | 95.16 | −0.36 | 0.1 |
| treatment is not performed | | | | |
| PEDOT/PSS to which | ∞Ω/□ | 94.32 | 0.33 | 0.41 |
| NaOCl is added | | | | |

As shown in Table 1, in the case in which NaOCl is added to PEDOT/PSS, sheet resistance of PEDOT/PSS increases to the infinity, such that PEDOT/PSS is deactivated; however, there is no large difference between PEDOT/PSS on which treatment is not performed and PEDOT/PSS to which NaOCl is added, based on the L*a*b* color system. As a result, since a color of PEDOT/PSS is hardly changed even after NaOCl is added to PEDOT/PSS, even though PEDOT/PSS is selectively deactivated by the addition of NaOCl, a user may not visually recognize the difference.

As described above, since the absorbance or the color of the conductive polymer (PEDOT/PSS) is hardly changed after the oxidant (NaOCl) is added to the conductive polymer, the plating pattern according to the preferred embodiment of the present invention may be used in a touch panel, or the like, requiring excellent visibility.

Next, as shown in FIG. 5, an operation of forming the plating layer 140 through an electroplating process using the conductive polymer 120 as a seed layer is performed. Since the conductive polymer 120 is selectively deactivated by the deactivator in the above-mentioned operation, when the electroplating process is performed using the conductive polymer 120 as the seed layer in the present operation, the plating layer 140 is selectively formed only on portions 125 of the conductive polymer 120 except for the deactivated portions 123. As described above, since the plating layer 140 is selectively formed only on the portions 125 of the conductive polymer 120 except for the deactivated portions 123 after the conductive polymer 120 is selectively deactivated, a process of etching and patterning the plating layer 140 may be omitted. Therefore, it is possible to prevent a metal from being unnecessarily consumed. Meanwhile, the plating layer 140 may be made of copper (Cu), aluminum (Al), gold (Au), silver (Ag), titanium (Ti), palladium (Pd), chromium (Cr), or a combination thereof.

Additionally, after the deactivator is added to the conductive polymer 120, an operation of depressing or protruding a predetermined portion 110a of the base substrate 110 may be performed so that the conductive polymer 120 has a three-dimensional contact surface (See FIGS. 2A and 2B). Here, the predetermined portion 110a of the base substrate 110 may be depressed or protruded by having heat or pressure applied thereto. In addition, after the predetermined portion 110a of the base substrate 110 is depressed or protruded, the electroplating process is performed, thereby making it possible to form the plating layer 140 having the three-dimensional contact surface.

According to the preferred embodiment of the present invention, since the plating layer is formed only on the portions of the conductive polymer except for the deactivated portions using the conductive polymer as the seed layer after the conductive polymer is selectively deactivated, the plating layer needs not to be etched and patterned. Therefore, it is possible to prevent a metal from being unnecessarily consumed.

In addition, according to the preferred embodiment of the present invention, since the conductive polymer is selectively deactivated by having the deactivator added thereto rather than being etched and patterned, a difference in absorbance or color is hardly generated. Therefore, even though the plating pattern is used as a sensing electrode pattern of a touch panel, a problem is not generated in terms of visibility.

Further, according to the preferred embodiment of the present invention, since a predetermined portion of the base substrate may be depressed or protruded due to excellent flexibility of the conductive polymer, it is possible to form the plating layer so as to have a three-dimensional contact surface.

Although the preferred embodiments of the present invention have been disclosed for illustrative purposes, they are for specifically explaining the present invention and thus a plating pattern and a method of manufacturing the same according to the present invention are not limited thereto, but those skilled in the art will appreciate that various modifications, additions and substitutions are possible, without departing from the scope and spirit of the invention as disclosed in the accompanying claims. Accordingly, any and all modifications, variations or equivalent arrangements should be considered to be within the scope of the invention, and the detailed scope of the invention will be disclosed by the accompanying claims.

What is claimed is:

1. A plating pattern comprising:
a base substrate;
a conductive polymer formed on the base substrate and patterned to be selectively deactivated by having a deactivator added thereto; and
a plating layer formed on portions of the conductive polymer except for the deactivated portions.

2. The plating pattern as set forth in claim 1, wherein the deactivator is an oxidant.

3. The plating pattern as set forth in claim 2, wherein the oxidant is O₃, NaOCl, KMnO₄, K₂Cr₂O₇, or amine oxide.

4. The plating pattern as set forth in claim 1, wherein the conductive polymer is poly-3,4-ethylenedioxythiophene/polystyrenesulfonate (PEDOT/PSS), polyaniline, polyacetylene, or polyphenylenevinylene

5. The plating pattern as set forth in claim 1, wherein a predetermined portion of the base substrate is depressed or protruded so that the plating layer has a three-dimensional contact surface.

6. A method of manufacturing a plating pattern, the method comprising:
(A) forming a conductive polymer on a base substrate;
(B) pattering the conductive polymer so as to be selectively deactivated by adding a deactivator thereto; and
(C) forming a plating layer through an electroplating process using the conductive polymer as a seed layer.

7. The method as set forth in claim 6, wherein in step (B), the deactivator is an oxidant.

8. The method as set forth in claim 6, wherein in step (C), the plating layer is formed on portions of the conductive polymer except for the deactivated portions.

9. The method as set forth in claim 7, wherein the oxidant is O₃, NaOCl, KMnO₄, K₂Cr₂O₇, or amine oxide.

10. The method as set forth in claim 6, wherein the conductive polymer is poly-3,4-ethylenedioxythiophene/polystyrenesulfonate (PEDOT/PSS), polyaniline, polyacetylene, or polyphenylenevinylene.

11. The method as set forth in claim 6, further comprising, after step (B), depressing or protruding a predetermined portion of the base substrate so that the conductive polymer has a three-dimensional contact surface.
